(19) United States
(12) Patent Application Publication
(10) Pub. No.: US 2014/0353010 A1
(43) Pub. Date: Dec. 4, 2014

(54) Electronic Component and Method of Manufacturing the Electronic Component

(71) Applicant: Cheng Uei Precision Industry Co., Ltd., New Taipei City (TW)

(72) Inventor: Chih Wei Wang, New Taipei City (TW)

(73) Assignee: Cheng Uei Precision Industry Co., Ltd., New Taipei City (TW)

(21) Appl. No.: 13/905,078

(22) Filed: May 29, 2013

(51) Int. Cl. H05K 1/02; H05K 3/22

(52) U.S. Cl. CPC H05K 1/0281; H05K 3/22; H05K 2201/05; H05K 2201/0203; H05K 2203/1327
USPC 174/254; 264/272.17

(57) ABSTRACT

An electronic component includes a flexible printed circuit board which has a main body, a fixing portion and a connecting portion, and an insulating portion integrally molded to the fixing portion. In the process of the insulating portion being molded to the fixing portion, a filling mold fixture is sleeved around and spaced from outsides of the fixing portion. A method of manufacturing the electronic component is described hereinafter. Sleeve the filling mold fixture around the fixing portion and apart from the outsides of the fixing portion. Place the flexible printed circuit board together with the filling mold fixture in a mold. Inject liquid rubber into the filling mold fixture. Close the mold. Cool the electronic component and the filling mold fixture. Open the mold to take out the electronic component and the filling mold fixture, and then separate the filling mold fixture from the electronic component smoothly.

### BACKGROUND OF THE INVENTION

1. Field of the Invention

The present invention generally relates to an electronic component, and more particularly to an electronic component applied to a consumer electronic product and a method of manufacturing the electronic component.

2. The Related Art

Referring to FIG. 9, a conventional electronic component 100′ adapted for being applied to a consumer electronic product (not shown) includes a flexible printed circuit board 10′ and an insulating portion 20′. The insulating portion 20′ is molded to the flexible printed circuit board 10′ by means of injection molding technology and usually made of TPE (Thermoplastic Elastomer), TPR (Thermoplastic Rubber) or TPU (Thermoplastic Polyurethanes). A method of manufacturing the conventional electronic component 100′ includes the following steps: step one, place the flexible printed circuit board 10′ inside an injection mold (not shown) and close the injection mold; step two, inject molten TPE, TPR or TPU into the injection mold to mold the insulating portion 20′ to the flexible printed circuit board 10′ for manufacturing the electronic component 100′; step three, cool the electronic component 100′ in the injection mold; step four, open the injection mold and take out the electronic component 100′.

Though the aforesaid insulating portion 20′ has a better combination performance with the flexible printed circuit board 10′ by means of the injection molding technology, nevertheless, the material for making the insulating portion 20′ is hard. And in the process of manufacturing the electronic component 100′, the processes of closing the injection mold and opening the injection mold are needed that often causes a spue line 21′ to be formed around the insulating portion 20′ and further results in waste materials 22′ around a periphery of the spue line 21′.

Referring to FIG. 9 again, in order to solve the above-mentioned problem that the material for making the insulating portion 20′ is hard, the insulating portion 20′ is molded to the flexible printed circuit board 10′ by means of thermo-compression formation technology and made of silicone. Another method of manufacturing the electronic component 100′ includes the following steps: step one, adhere two pieces of silicone sheets respectively to a top surface and a bottom surface of the flexible printed circuit board 10′ by interface adhesives; step two, place the flexible printed circuit board 10′ with the two silicone sheets inside a thermo-compression mold (not shown); step three, close the thermo-compression mold, then heat soften and thermo-compress the silicone sheets to form the insulating portion 20′ to the flexible printed circuit board 10′ for manufacturing the electronic component 100′; step four, cool the electronic component 100′ in the thermo-compression mold; step five, open the thermo-compression mold and take out the electronic component 100′. Though the silicone sheets for making the insulating portion 20′ conform to a hardness requirement of the electronic component 100′, nevertheless, in the process of manufacturing the electronic component 100′, the processes of closing the thermo-compression mold and opening the thermo-compression mold are still needed that would still cause the spue line 21′ to be formed around the insulating portion 20′ with the waste materials 22′ around the periphery of the spue line 21′, moreover that would further cause an interstice between the two silicone sheets.

As described above, the material for molding the aforesaid insulating portion 20′ by means of the injection molding technology is hard. Furthermore, the methods of manufacturing the electronic component 100′ by virtue of the injection molding technology and the thermo-compression formation technology need the processes of closing and opening the injection mold and the processes of closing and opening the thermo-compression mold, so the spue line 21′ and the waste materials 22′ are often formed around the insulating portion 20′ so that often results in an interstice between the electronic component 100′ and the consumer electronic product. Moreover, the method of manufacturing the electronic component 100′ by virtue of the thermo-compression formation technology easily causes the interstice between the two silicone sheets. As a result, a waterproof function of the insulating portion 20′ for the flexible printed circuit board 10′ and the consumer electronic product is affected.

### SUMMARY OF THE INVENTION

An object of the present invention is to provide an electronic component adapted for being applied to a consumer electronic product and a method of manufacturing the electronic component. The electronic component includes a flexible printed circuit board and an insulating portion. The flexible printed circuit board has a main body, a fixing portion connecting with a rear end of the main body, and a connecting portion connecting with a rear end of the fixing portion, the connecting portion is further electrically connected with the consumer electronic product. The insulating portion is integrally molded to the fixing portion of the flexible printed circuit board. In the process of the insulating portion being molded to the fixing portion of the flexible printed circuit board, a filling mold fixture is sleeved around and spaced from outsides of the fixing portion of the flexible printed circuit board to mold the insulating portion between the filling mold fixture and the fixing portion of the flexible printed circuit board. The method of manufacturing the electronic component is described hereinafter. Sleeve filling mold fixture around the fixing portion of the flexible printed circuit board and apart from the outsides of the fixing portion. Open a mold for molding the electronic component, and then place the flexible printed circuit board together with the filling mold fixture in a set position of the mold. Inject liquid rubber into the filling mold fixture. Close the mold to make the insulating portion integrally molded to the fixing portion of the flexible printed circuit board for manufacturing the electronic component. Cool the electronic component and the filling mold fixture. Open the mold to take out the electronic component and the filling mold fixture, and then separate the filling mold fixture from the electronic component smoothly.

As described above, the filling mold fixture is sleeved around and spaced from the outsides of the fixing portion of the flexible printed circuit board, so the insulating portion is molded between the filling mold fixture and the fixing portion of the flexible printed circuit board, and in the process of manufacturing the electronic component, inject the liquid rubber into the filling mold fixture, then the insulating portion integrally molded to the fixing portion of the flexible printed circuit board so as to make the insulating portion and the flexible printed circuit board have the better combination performance and the material for molding the insulating portion by means of the above-mentioned method conforms to the hardness requirement of the electronic component, and an outer surface of the insulating portion is smooth to make the electronic component combine with the matching element tightly. As a result, a waterproof function between the electronic component and the consumer electronic product is ensured.

### BRIEF DESCRIPTION OF THE DRAWINGS

The present invention will be apparent to those skilled in the art by reading the following description, with reference to the attached drawings, in which:

FIG. 1 is a perspective view of an electronic component in accordance with an embodiment of the present invention;

FIG. 2 is a perspective view of the electronic component of FIG. 1, wherein a flexible printed circuit board of the electronic component passes through a filling mold fixture used for molding an insulating portion of the electronic component;

FIG. 3 is a perspective view of the electronic component of FIG. 1, wherein the electronic component is partially separated from the filling mold fixture;

FIG. 4 is a perspective view of the electronic component of FIG. 1, wherein the electronic component is completely separated from the filling mold fixture;

FIG. 5 is a perspective view of the electronic component of FIG. 1, wherein a strengthening element and two conducting pieces are disposed on the electronic component;

FIG. 6 is another perspective view of the electronic component of FIG. 1, wherein the strengthening element and the conducting pieces are disposed on the electronic component;

FIG. 7 is a perspective view of the electronic component of FIG. 1, wherein the electronic component is applied to a consumer electronic product;

FIG. 8 is a perspective view of the electronic component put in a set position of a mold for molding the electronic component of FIG. 1; and

FIG. 9 is a perspective view of a conventional electronic component.

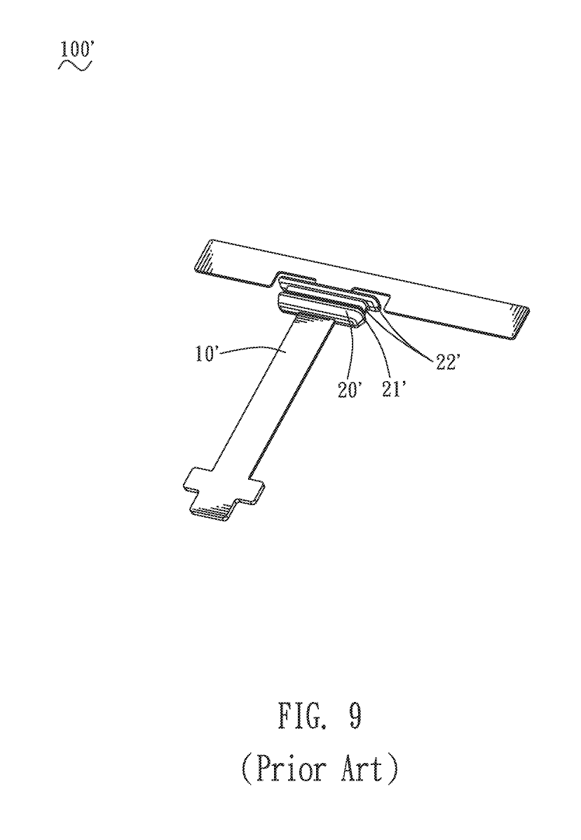

### DETAILED DESCRIPTION OF THE PREFERRED EMBODIMENT

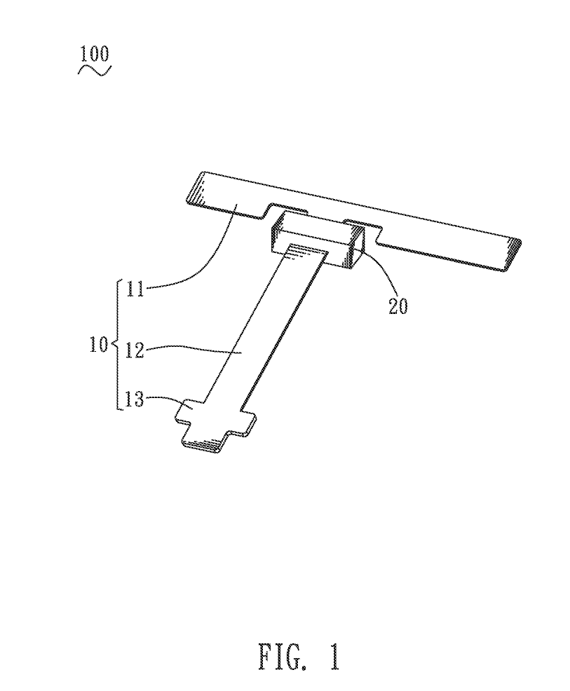

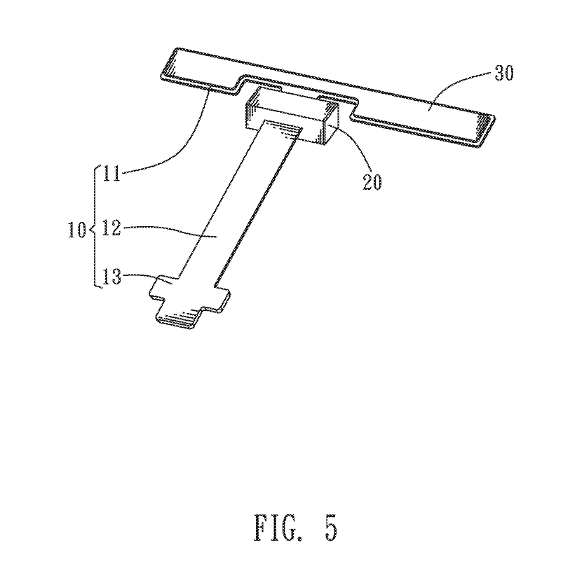

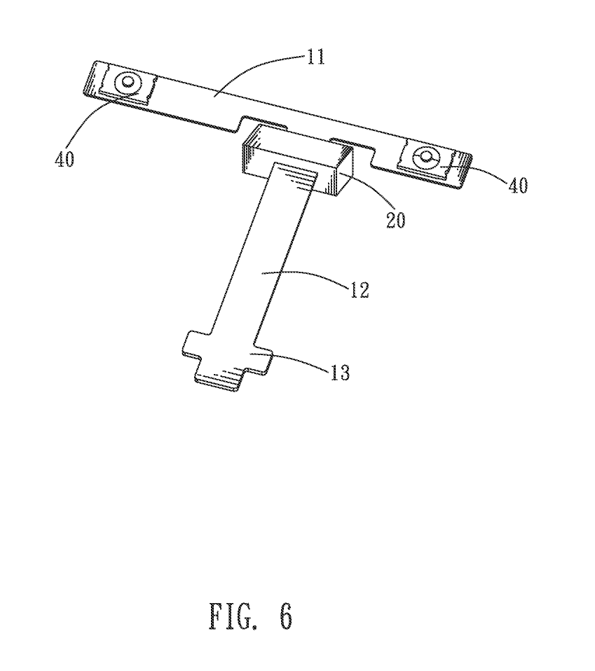

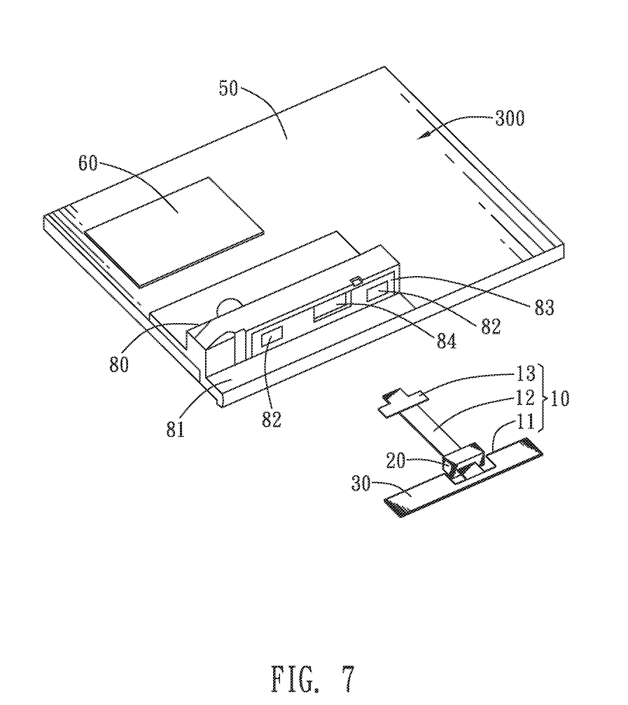

With reference to FIG. 1, FIG. 5, FIG. 6 and FIG. 7, an electronic component 100 in accordance with an embodiment of the present invention is shown. The electronic component 100 adapted for being applied to a consumer electronic product 300 includes a flexible printed circuit board 10, an insulating portion 20 integrally molded to the flexible printed circuit board 10, a strengthening element 30 and two conducting pieces 40.

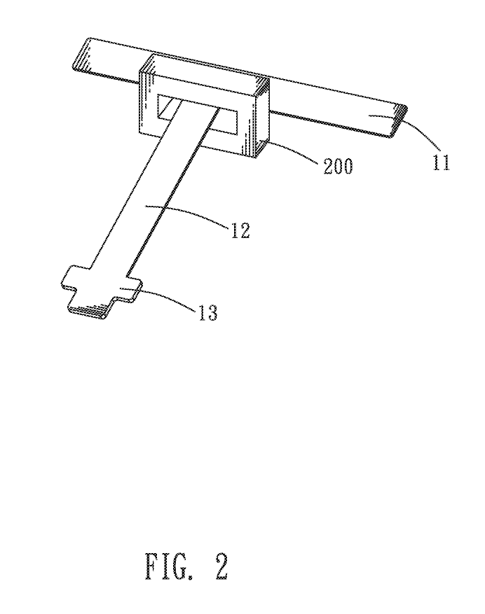

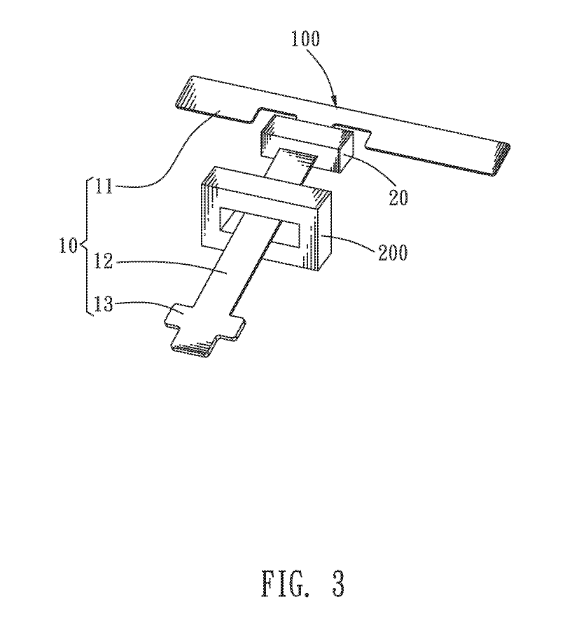

Referring to FIG. 1, FIG. 2, FIG. 3, FIG. 5, FIG. 6 and FIG. 7, the flexible printed circuit board 10 has a main body 11, a fixing portion 12 connecting with a rear end of the main body 11, and a connecting portion 13 connecting with a rear end of the fixing portion 12. The connecting portion 13 is further electrically connected with the consumer electronic product 300. The insulating portion 20 is integrally molded to the fixing portion 12 of the flexible printed circuit board 10. In the process of the insulating portion 20 being molded to the fixing portion 12 of the flexible printed circuit board 10, a filling mold fixture 200 is sleeved around and spaced from outsides of the fixing portion 12 of the flexible printed circuit board 10 to mold the insulating portion 20 between the filling mold fixture 200 and the fixing portion 12 of the flexible printed circuit board 10. The insulating portion 20 is made of silicone. A hardness of the insulating portion 20 is requested at shore A50±5, and a waterproof standard is requested to be IPX7. The two conducting pieces 40 are disposed on a bottom of the main body 11 and spaced from each other at two opposite sides of the fixing portion 12, and the strengthening element 30 is disposed on a top of the main body 11.

Referring to FIG. 1, FIG. 5, FIG. 6 and FIG. 7, the consumer electronic product 300 includes a base portion 50, a circuit board 60 disposed on the base portion 50 and a matching element 80 disposed to the base portion 50. The matching element 80 includes a fastening element 81 and two contact pieces 82. A front face of the fastening element 81 defines a receiving groove 83. A substantial middle of a rear sidewall of the receiving groove 83 defines a fastening hole 84 penetrating rearward through the fastening element 81. The two contact pieces 82 are disposed on the rear sidewall of the receiving groove 83 and located at two opposite sides of the fastening hole 84. When the electronic component 100 is applied to the consumer electronic product 300, the connecting portion 13 of the flexible printed circuit board 10 passes through the fastening hole 84 of the matching element 80 to electrically connect with the circuit board 60 of the consumer electronic product 300. The insulating portion 20 is fastened in the fastening hole 84 to combine the electronic component 100 with the matching element 80 tightly. Then the main body 11 together with the strengthening element 30 is bent downward to be received in the receiving groove 83. The two conducting pieces 40 of the electronic component 100 electrically contact with the two contact pieces 82 respectively.

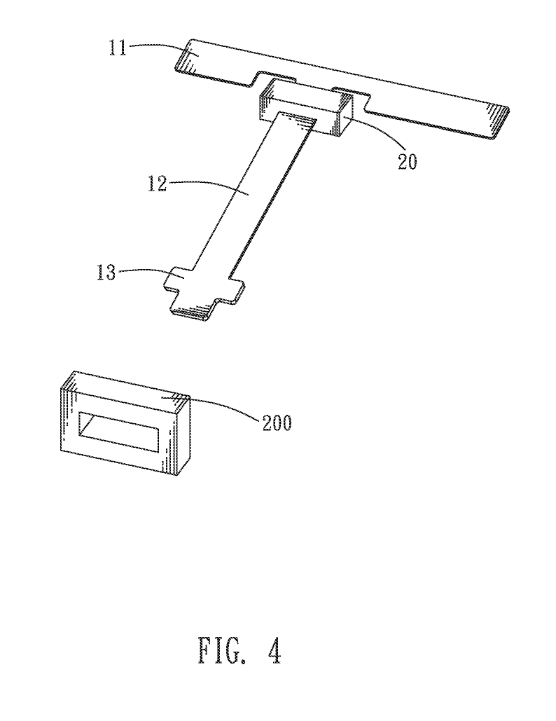

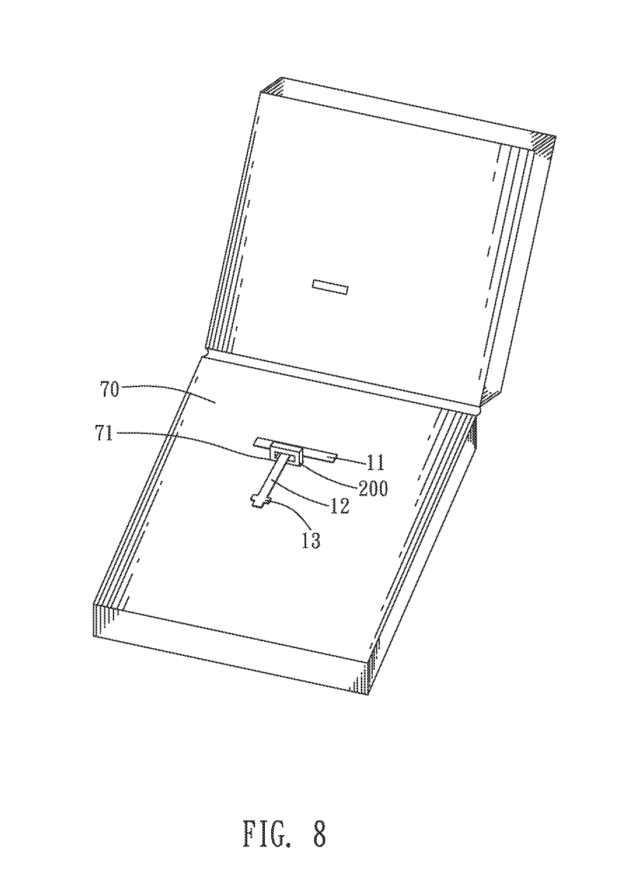

Referring to FIG. 1, FIG. 2, FIG. 3, FIG. 4, FIG. 7 and FIG. 8, specific steps of a method of manufacturing the electronic component 100 in accordance with the embodiment of the present invention are described as follows.

Step one: sleeve the filling mold fixture 200 around the fixing portion 12 of the flexible printed circuit board 10 and apart from the outsides of the fixing portion 12.

Step two: open a mold 70 for molding the electronic component 100, and then place the flexible printed circuit board 10 together with the filling mold fixture 200 in a set position 71 of the mold 70.

Step three: inject liquid rubber into the filling mold fixture 200.

Step four: close the mold 70 to make the insulating portion 20 integrally molded to the fixing portion 12 of the flexible printed circuit board 10 for manufacturing the electronic component 100.

Step five: cool the electronic component 100 and the filling mold fixture 200.

Step six: open the mold 70 to take out the electronic component 100 and the filling mold fixture 200, and then separate the filling mold fixture 200 from the electronic component 100 smoothly.

The liquid rubber is liquid silicone, so the insulating portion 20 and the flexible printed circuit board 10 have a better combination performance and the material of the insulating portion 20 conforms to the hardness requirement of the electronic component 100.

As described above, the filling mold fixture 200 is sleeved around and spaced from the outsides of the fixing portion 12 of the flexible printed circuit board 10, so the insulating portion 20 is molded between the filling mold fixture 200 and the fixing portion 12 of the flexible printed circuit board 10, and in the process of manufacturing the electronic component 100, inject the liquid rubber into the filling mold fixture 200, then the insulating portion 20 integrally molded to the fixing portion 12 of the flexible printed circuit board 10 so as to make the insulating portion 20 and the flexible printed circuit board 10 have the better combination performance and the material for molding the insulating portion 20 by means of the above-mentioned method conforms to the hardness requirement of the electronic component 100, and an outer surface of the insulating portion 20 is smooth to make the electronic component 100 combine with the matching element 80 tightly. As a result, a waterproof function between the electronic component 100 and the consumer electronic product 300 is ensured.

What is claimed is:

1. An electronic component adapted for being applied to a consumer electronic product, comprising:
a flexible printed circuit board having a main body, a fixing portion connecting with a rear end of the main body, and a connecting portion connecting with a rear end of the fixing portion, the connecting portion being further electrically connected with the consumer electronic product; and
an insulating portion integrally molded to the fixing portion of the flexible printed circuit board;
wherein in the process of the insulating portion being molded to the fixing portion of the flexible printed circuit board, a filling mold fixture is sleeved around and spaced from outsides of the fixing portion of the flexible printed circuit board to mold the insulating portion between the filling mold fixture and the fixing portion of the flexible printed circuit board.

2. The electronic component as claimed in claim 1, wherein the electronic component further includes a strengthening element and two conducting pieces, the two conducting pieces are disposed on a bottom of the main body and spaced from each other at two opposite sides of the fixing portion, and the strengthening element is disposed on a top of the main body.

3. The electronic component as claimed in claim 2, wherein the consumer electronic product includes a base portion, a circuit board disposed on the base portion and a matching element disposed to the base portion, the matching element includes a fastening element and two contact pieces, a front face of the fastening element defines a receiving groove, a substantial middle of a rear sidewall of the receiving groove defines a fastening hole penetrating rearward through the fastening element, the two contact pieces are disposed on the rear sidewall of the receiving groove and located at two opposite sides of the fastening hole, the connecting portion of the flexible printed circuit board passes through the fastening hole of the matching element to electrically connect with the circuit board, the insulating portion is fastened in the fastening hole to combine the electronic component with the matching element tightly, then the main body together with the strengthening element is bent downward to be received in the receiving groove, the two conducting pieces of the electronic component electrically contact with the two contact pieces respectively.

4. The electronic component as claimed in claim 1, wherein the insulating portion is made of silicone, a hardness of the insulating portion is requested at shore A50±5, and a waterproof standard is requested to be IPX7.

5. A method of manufacturing the electronic component as claimed in claim 1, comprising the steps of:
sleeving the filling mold fixture around the fixing portion of the flexible printed circuit board and apart from the outsides of the fixing portion;
opening a mold for molding the electronic component, and then placing the flexible printed circuit board together with the filling mold fixture in a set position of the mold;
injecting liquid rubber into the filling mold fixture;
closing the mold to make the insulating portion integrally molded to the fixing portion of the flexible printed circuit board for manufacturing the electronic component;
cooling the electronic component and the filling mold fixture; and
opening the mold to take out the electronic component and the filling mold fixture, and then separating the filling mold fixture from the electronic component.

6. The method as claimed in claim 5, wherein the liquid rubber is liquid silicone.
